(19) United States
(12) Patent Application Publication
(10) Pub. No.: US 2017/0011144 A1
(43) Pub. Date: Jan. 12, 2017

(54) HIGH-VOLTAGE DEVICE SIMULATION MODEL AND MODELING METHOD THEREFOR

(71) Applicant: CSMC TECHNOLOGIES FAB1 CO., LTD., Wuxi New District (CN)

(72) Inventors: Yifeng HU, Wuxi New District (CN); Xiaodong HE, Wuxi New District (CN); Xinxin LIU, Wuxi New District (CN)

(21) Appl. No.: 15/119,249

(22) PCT Filed: May 8, 2015
(86) PCT No.: PCT/CN2015/078552

§ 371 Date: Aug. 16, 2016

(30) Foreign Application Priority Data
May 8, 2014 (CN) 201410194101.7

(51) Int. Cl. G06F 17/50; H01L 27/02

(52) U.S. Cl. CPC G06F 17/5009; H01L 27/0207

(57) ABSTRACT

A high-voltage device simulation model and a modeling method thereof are provided. The simulation model comprises: a core transistor (101), a drain terminal resistor (102) and a source terminal resistor (103), wherein a first terminal of the drain terminal resistor (102) is electrically connected to a drain (d1) of the core transistor (101) and a second terminal of the drain terminal resistor (102) serves as the drain of the high voltage device; a first terminal of the source terminal resistor (103) is electrically connected to a source (s1) of the core transistor (101) and a second terminal of the source terminal resistor (103) serves as the source of the high voltage device. The relations of the resistance value of the drain terminal resistor (102) are as follows: RD=(RD0/W)*(1+CRD*V_{D}^{ERDD}+1/(1+PRWDD*V_{D}^{ERDD}))*TFAC_RD, and TFAC_RD=(1+TCRD1*(TEMP−25)+TCRD2*(TEMP−25)*(TEMP−25)).

### FIELD OF THE INVENTION

The present invention relates to a field of integrated circuit, and particularly relates to a simulation model of a high voltage device and a modeling method of the simulation model of the high voltage device.

### BACKGROUND OF THE INVENTION

In recent years, the high voltage devices are widely applied to the integrated circuit products, for example, the high voltage devices can be used in the circuits such as power management chips and the like. With the extensive application of the high voltage devices, in the integrated circuit design, the accuracy required for a simulation model of the high voltage devices is also increased. The special structure of the high voltage devices determines that these devices have greater parasitic effects, such as the typical quasi-saturation effect. The quasi-saturation effect means that when the gate voltage increases, compared with the conventional MOSFET transistor, the increasing speed of saturation current in the high voltage transistor device reduces significantly, that is to say, in a case of a high gate voltage the control capability for drain current by the gate voltage greatly reduces. This causes that most widely used standard model BSIM3, BSIM4 in the art cannot well fit this kind of high voltage characteristic. Currently, the simulation model of the high voltage devices has a high cost, a low efficiency and a low accuracy and is time consuming. Especially for the ultra high voltage devices of which the drain source voltage reaches 700V or more, it is difficult for current simulation model to satisfy the requirement for simulation accuracy.

### SUMMARY OF THE INVENTION

Accordingly, it is necessary to provide a simulation model of a high voltage device and a modeling method thereof, which can have a higher efficiency and simulate characteristics of the high voltage device accurately.

A simulation model of a high voltage device includes a core transistor; a drain terminal resistor, wherein a first terminal of the drain terminal resistor is electrically coupled to a drain of the core transistor and a second terminal of the drain terminal resistor serves as a drain of the high voltage device; and a source terminal resistor, wherein a first terminal of the source terminal resistor is electrically coupled to a source of the core transistor and a second terminal of the source terminal resistor serves as a source of the high voltage device; wherein, a relationship among a resistance value of the drain terminal resistor, a voltage applied to the drain terminal resistor, a temperature and a width of the high voltage device is:

RD=(RD0/W)*(1+CRD*V_{D}^{ERDD}+1/(1+PRWDD*V_{D}^{ERDD}))*TFAC_RD, TFAC_RD=(1+TCRD1*(TEMP−25)+TCRD2*(TEMP−25)*(TEMP−25));
wherein a relationship among a resistance value of the source terminal resistor and a voltage applied to the source terminal resistor, the temperature and the width of the high voltage device is:

RS=(RS0/W)*(1+CRS*V_{S}^{ERSS}+1/(1+PRWSS*V_{S}^{ERSS}))TFAC_RS, TFAC_RS=(1+TCRS1*(TEMP−25)+TCRS2*(TEMP−25)*(TEMP−25));

V_{D} is an absolute value of the voltage applied to the drain terminal resistor, RD0 is the resistance value of the drain terminal resistor when the voltage is 0, CRD is a first voltage coefficient of the drain terminal resistor, ERDD is an exponent term coefficient of the voltage of the drain terminal resistor, PRWDD is a second voltage coefficient of the drain terminal resistor, TCRD1 is a one degree term temperature coefficient of the drain terminal resistor, TCRD2 is a quadratic term temperature coefficient of the drain terminal resistor, V_{S} is an absolute value of the voltage applied to the source terminal resistor, RS0 is the resistance value of the source terminal resistor when the voltage is 0, CRS is a first voltage coefficient of the source terminal resistor, ERSS is an exponent term coefficient of the voltage of the source terminal resistor, PRWSS is a second voltage coefficient of the source terminal resistor, TCRS 1 is a one degree term temperature coefficient of the source terminal resistor, TCRS2 is a quadratic term temperature coefficient of the source terminal resistor, TEMP is a system temperature, W is a channel width of the high voltage device.

A modeling method of a simulation model of a high voltage device includes establishing a model of a core transistor; establishing a model of a drain terminal resistor; electrically coupling a first terminal of the drain terminal resistor to a drain of the core transistor; establish a model of a source terminal resistor; and electrically coupling a first terminal of the source terminal resistor to a source of the core transistor; wherein, a relationship among a resistance value of the drain terminal resistor, a voltage applied to the drain terminal resistor, a temperature and a width of the high voltage device is:

RD=(RD0/W)*(1+CRD*V_{D}^{ERDD}+1/(1+PRWDD*V_{D}^{ERDD}))*TFAC_RD, TFAC_RD=(1+TCRD1*(TEMP−25)+TCRD2*(TEMP−25)*(TEMP−25));

wherein a relationship among a resistance value of the source terminal resistor, a voltage applied to the source terminal resistor, the temperature and the width of the high voltage device is:

RS=(RS0/W)*(1+CRS*V_{S}^{ERSS}+1/(1+PRWSS*V_{S}^{ERSS}))TFAC_RS, TFAC_RS=(1+TCRS 1*(TEMP−25)+TCRS2*(TEMP−25)*(TEMP−25));

V_{D} is an absolute value of the voltage applied to the drain terminal resistor, RD0 is the resistance value of the drain terminal resistor when the voltage is 0, CRD is a first voltage coefficient of the drain terminal resistor, ERDD is an exponent term coefficient of the voltage of the drain terminal resistor, PRWDD is a second voltage coefficient of the drain terminal resistor, TCRD1 is a one degree term temperature coefficient of the drain terminal resistor, TCRD2 is a quadratic term temperature coefficient of the drain terminal resistor, V_{S} is an absolute value of the voltage applied to the source terminal resistor, RS0 is the resistance value of the source terminal resistor when the voltage is 0, CRS is a first voltage coefficient of the source terminal resistor, ERSS is an exponent term coefficient of the voltage of the source terminal resistor, PRWSS is a second voltage coefficient of the source terminal resistor, TCRS1 is a one degree term temperature coefficient of the source terminal resistor, TCRS2 is a quadratic term temperature coefficient of the source terminal resistor, TEMP is a system temperature, W is a channel width of the high voltage device.

The above simulation model uses an improved formula among a resistance value and the voltage, the temperature and the width of the high voltage device to correct the resistance value of the voltage-controlled resistor externally coupled to the high voltage device model, which improves the simulation accuracy of the high voltage device model. Even for the ultra high voltage device, such as the ultra high voltage device of which the drain source voltage V_{ds} reaches 700V or more, the high voltage device model can also have a great high simulation accuracy.

### BRIEF DESCRIPTION OF THE DRAWINGS

To illustrate the technical solutions according to the embodiments of the present invention or in the prior art more clearly, the accompanying drawings for describing the embodiments or the prior art are introduced briefly in the following. Apparently, the accompanying drawings in the following description are only some embodiments of the present invention, and persons of ordinary skill in the art can derive other drawings from the accompanying drawings without creative efforts.

FIG. 1 shows a schematic circuit diagram of a simulation model of a high voltage device in an embodiment;

FIG. 2 shows a flow chart of a modeling method of the simulation model of the high voltage device in an embodiment;

FIGS. 3a-3d are graphs showing curves representing a relationship between a current characteristic and a voltage characteristic for simulating an exemplary high voltage device by using the simulation model of the high voltage device in an embodiment.

### DETAILED DESCRIPTION OF THE EMBODIMENTS

The above objects, features and advantages of the present invention will become more apparent by describing in detail embodiments thereof with reference to the accompanying drawings. It should be understood that specific embodiments described herein are only used to explain the invention without limiting the invention.

In the context, “a low voltage”, “a high voltage” and “an ultra high voltage” are distinguished by magnitudes of a gate voltage VGS and a drain source voltage VDS. “a low voltage” refers to 0V≦VGS<5V and 0V≦VDS<5V. “a high voltage” refers to 5V≦VGS≦40V and 5V≦VDS<200V. “an ultra high voltage” refers to VGS≧5V and VDS≧200V, for example VDS is 700V. Further, in the context, “first” and “second” are just used to make a distinction, which does not define any order.

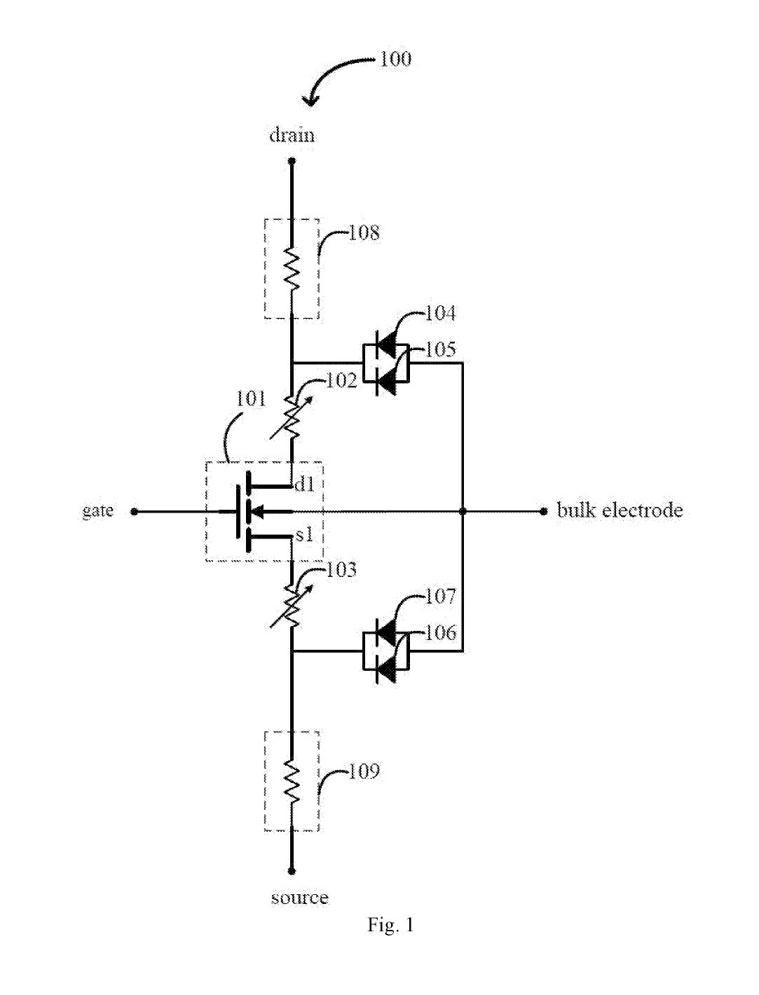

According to an embodiment of the invention, a simulation model of a high voltage device is provided. FIG. 1 shows a circuit schematic view of a simulation model 100 of a high voltage device in an embodiment. As shown in FIG. 1, the simulation model 100 includes a core transistor 101, a drain terminal resistor 102 and a source terminal resistor 103. A first terminal of the drain terminal resistor 102 is electrically coupled to a drain d1 of the core transistor 100 and a second terminal of the drain terminal resistor 102 serves as a drain of the high voltage device. A first terminal of the source terminal resistor 103 is electrically coupled to a source s1 of the core transistor 100 and a second terminal of the source terminal resistor 103 serves as a source of the high voltage device. Further, a gate of the core transistor 100 can serve as a gate of the high voltage device. A bulk electrode of the core transistor 100 can serve as a bulk electrode of the high voltage device. The drain terminal resistor 102 and the source terminal resistor 103 are parasitic resistors of a source terminal and a drain terminal of the high voltage device respectively. Both the source terminal resistor 102 and the drain terminal resistor 103 use a mode of the voltage-controlled resistor. The source terminal resistor 102 can simulate a case that the control capacity for the drain current by the gate voltage reduces under a high gate voltage, i.e. the quasi-saturation effect. When the drain structure and the source structure of the high voltage device are symmetrical, the drain terminal resistor 102 and the source terminal resistor 103 can be same, that is to say, they can use a same resistor model. On the contrary, when the drain structure and the source structure of the high voltage device are not symmetrical, the drain terminal resistor 102 and the source terminal resistor 103 can be different, that is to say, they can use different resistor models.

A relationship among a resistance value of the drain terminal resistor 102, a voltage applied to the drain terminal resistor 102, a temperature and a width of the high voltage device is:

RD=(RD0/W)*(1+CRD*V_{D}^{ERDD}+1/(1+PRWDD*V_{D}^{ERDD}))*TFAC_RD, TFAC_RD=(1+TCRD1*(TEMP−25)+TCRD2*(TEMP−25)*(TEMP−25));

A relationship among a resistance value of the source terminal resistor 103, a voltage applied to the source terminal resistor 103, the temperature and the width of the high voltage device is:

RS=(RS0/W)*(1+CRS*V_{S}^{ERSS}+1/(1+PRWSS*V_{S}^{ERSS}))*TFAC_RS, TFAC_RS=(1+TCRS1*(TEMP−25)+TCRS2*(TEMP−25)*(TEMP−25));

where V_{D} is an absolute value of the voltage applied to the drain terminal resistor 102, RD0 is the resistance value of the drain terminal resistor 102 when the voltage is 0, CRD is a first voltage coefficient of the drain terminal resistor 102, ERDD is an exponent term coefficient of the voltage of the drain terminal resistor 102, PRWDD is a second voltage coefficient of the drain terminal resistor 102, TCRD1 is a one degree term temperature coefficient of the drain terminal resistor 102, TCRD2 is a quadratic term temperature coefficient of the drain terminal resistor 102, V_{S} is an absolute value of the voltage applied to the source terminal resistor 103, RS0 is the resistance value of the source terminal resistor 103 when the voltage is 0, CRS is a first voltage coefficient of the source terminal resistor 103, ERSS is an exponent term coefficient of the voltage of the source terminal resistor 103, PRWSS is a second voltage coefficient of the source terminal resistor 103, TCRS1 is a one degree term temperature coefficient of the source terminal resistor 103, TCRS2 is a quadratic term temperature coefficient of the source terminal resistor 103, TEMP is a system temperature, W is a channel width of the high voltage device. Those skilled in the art can understand that the channel width of the high voltage device can be equal to a channel width of the core transistor 100, and a channel length of the high voltage device can be equal to a channel length of the core transistor 100.

A formula of an externally coupled resistor provided by an embodiment facilitates simulating characteristics of the high voltage device precisely. In the following, it is illustrated by using the source terminal resistor 103 as an example. In the formula among a resistance value of the source terminal resistor 103 and a voltage V_{S} applied to the source terminal resistor, the system temperature TEMP and the channel width W of the high voltage device, an exponent term coefficient ERSS related to V_{S} and voltage coefficients CRS and PRWSS thereof are used. The formula can well fit the tendency of RS with the change of the voltage. The change tendency presents a monotonically increasing or decreasing case and approximates to a certain value infinitely. Because RS can approximate to a certain value infinitely with increasing of the voltage, it can fit a case that the drain current I_{ds} increases slowly and tends to be steady gradually after entering into a saturation region, and then infinite increasing of RS will not cause that the drain current begins to decrease when the gate voltage increases to a certain value. Therefore, parameters CRS, ERSS, PRWSS can facilitate fitting the quasi-saturation effect in the high voltage device characteristics. Similarly, because the formula among a resistance value of the drain terminal resistor 102 and a voltage V_{D} applied to the drain terminal resistor, the system temperature TEMP and the channel width W of the high voltage device uses an exponent term coefficient ERDD related to V_{D} and voltage coefficients CRD and PRWDD thereof, the formula can well fit the tendency of RD with the change of the voltage. Parameters CRD, ERDD, PRWDD can facilitate fitting the voltage-controlled characteristic of the parasitic resistor of the drain terminal in the high voltage device characteristics. Further, each temperature coefficient used in the above formula can facilitate fitting the high voltage device characteristics under different temperatures.

The simulation model 100 of the high voltage device provided in an embodiment uses an improved formula among a resistance value and the voltage, the temperature and the width of the high voltage device to correct the resistance value of the voltage-controlled resistor externally coupled to the high voltage device model, which improves the simulation accuracy of the high voltage device model. Even for the ultra high voltage device, such as the ultra high voltage device of which the drain source voltage V_{ds} reaches 700V or more, the high voltage device model can also have a great high simulation accuracy.

In an embodiment, the simulation model 100 further includes at least one drain terminal diode and at least one source terminal diode. Each of the at least one drain terminal diode is coupled in series between the second terminal of the drain terminal resistor and the bulk electrode of the core transistor. Each of the at least one source terminal diode is coupled in series between the second terminal of the source terminal resistor and the bulk electrode of the core transistor. A built-in diode of the core transistor 100 is turned off. Because the high voltage device are complex, the parasitic diode structure thereof is also complex, and then the manner using the built-in diode of the transistor simulation model is not flexible and the fitting result may be not correct. Therefore, in an embodiment, the externally coupled diode is used to illustrate characteristics of the parasitic diode of the high voltage device. The at least one drain terminal diode and the at least one source terminal diode are externally coupled diodes, and the user can set their each parameter according to requirement. The at least one drain terminal diode and the at least one source terminal diode can precisely illustrate the electric leakage characteristic, the capacitance characteristic of the parasitic diode and the dynamic parameter characteristic of the high voltage device, facilitating make the fitting result of the high voltage device more precise. Because the externally coupled diode is used, the built-in diode of the core transistor 101 has to be turned off. Those skilled in the art can understand that in the case that the drain structure and the source structure of the high voltage device are symmetrical, the at least one drain terminal diode and the at least one source terminal diode can be same. Therefore, a same simulation model can be used.

In an embodiment, the at least one drain terminal diode includes a first drain terminal diode 104 and a second drain terminal diode 105. The first drain terminal diode 104 is a parasitic diode located at an isolation region side of the high voltage device between the drain of the high voltage device and the bulk electrode of the high voltage device. The second drain terminal diode 105 is a parasitic diode located at a gate side of the high voltage device between the drain of the high voltage device and the bulk electrode of the high voltage device. Those skilled in the art can understand that when the high voltage device is a NMOS device, both an anode of the first drain terminal diode 104 and an anode of the second drain terminal diode 105 are electrically coupled to the bulk electrode of the high voltage device, and both a cathode of the first drain terminal diode 104 and a cathode of the second drain terminal diode 105 are electrically coupled to the second terminal of the drain terminal resistor 102. On the contrary, when the high voltage device is a PMOS device, both the anode of the first drain terminal diode 104 and the anode of the second drain terminal diode 105 are electrically coupled to the second terminal of the drain terminal resistor 102, and both the cathode of the first drain terminal diode 104 and the cathode of the second drain terminal diode 105 are electrically coupled to the bulk electrode of the high voltage device. Further, according to requirements, if in a simulated high voltage device the parasitic diode located at the isolation region side (i.e. adjacent to the isolation region) between the drain and the bulk electrode is the same as the parasitic diode located at the gate side (i.e. adjacent to the gate) between the drain and the bulk electrode, then the first drain terminal diode 104 and the second drain terminal diode 105 can use a same diode simulation model. The first drain terminal diode 104 and the second drain terminal diode 105 can be used to more precisely fit the case of the parasitic diode of the drain terminal of the high voltage device, further improving the simulation accuracy of the high voltage device.

In an embodiment, the at least one source terminal diode includes a first source terminal diode 106 and a second source terminal diode 107. The first source terminal diode 106 is a parasitic diode located at the isolation region side (i.e. adjacent to the isolation region) of the high voltage device between the source of the high voltage device and the bulk electrode of the high voltage device. The second source terminal diode 107 is a parasitic diode located at the gate side (i.e. adjacent to the gate) of the high voltage device between the source of the high voltage device and the bulk electrode of the high voltage device. According to the above description regarding to the first drain terminal diode 104 and the second drain terminal diode 105, those skilled in the art can understand the work principle and method of the first source terminal diode 106 and the second source terminal diode 107, which are not described here for clarity. The first source terminal diode 106 and the second source terminal diode 107 can be used to more precisely fit the case of the parasitic diode of the source terminal of the high voltage device, further improving the simulation accuracy of the high voltage device.

Optionally, the simulation model 100 can further include a drain terminal contact resistor 108 and/or a source terminal contact resistor 109. Those skilled in the art can understand that according to modeling requirements of devices of different properties the drain terminal contact resistor 108 and/or a source terminal contact resistor 109 can be added in the simulation model 100.

In an embodiment, CRD is a function of the channel length of the high voltage device. Those skilled in the art can understand that parameters CRD, PRWDD, ERDD, CRS, ERSS and PRWSS in the simulation model 100 of the high voltage device can be added, deleted, replaced, modified and the like according to requirements. For example, in the case that CRD is related to the channel length L of the high voltage device, CRD is a function of L, and CRD is changed with the change of L. However, of course, CRD can be any one of suitable constants such as 0, 1 and the like.

In an embodiment, CRD is a function of the channel width of the high voltage device. Those skilled in the art should understand that parameters CRD, PRWDD, ERDD, CRS, ERSS and PRWSS in the simulation model 100 of the high voltage device can be added, deleted, replaced, modified and the like according to requirements. For example, in the case that CRD is related to the channel width W of the high voltage device, CRD is a function of W, and CRD is changed with the change of W. However, of course, CRD can be any one of suitable constants such as 0, 1 and the like.

In an embodiment, the core transistor is fitted using a BSIM4 transistor model. At present, the BSIM4 transistor model is an universal standard transistor simulation model in the art, which can be supported by the currently main simulators and only need to be transformed into the format supported by the simulators. For example, the simulation model 100 using the BSIM4 transistor model can be applied to the simulation in Hspice of Synopsys, or the simulation in Spectre of Cadence. Use of the BSIM4 transistor model can avoid problems of increasing modeling difficulty, increasing cost and great requirement for data caused by non-universality of the model. When the BSIM4 transistor model simulates in different simulators, there is no difference, and the BSIM4 transistor model has a less requirement for the version of the simulator. Those skilled in the art should understand that when the simulation model 100 is used to simulate the high voltage device, parameters of BSIM4 can be used to fit the device characteristics in a case of a low voltage.

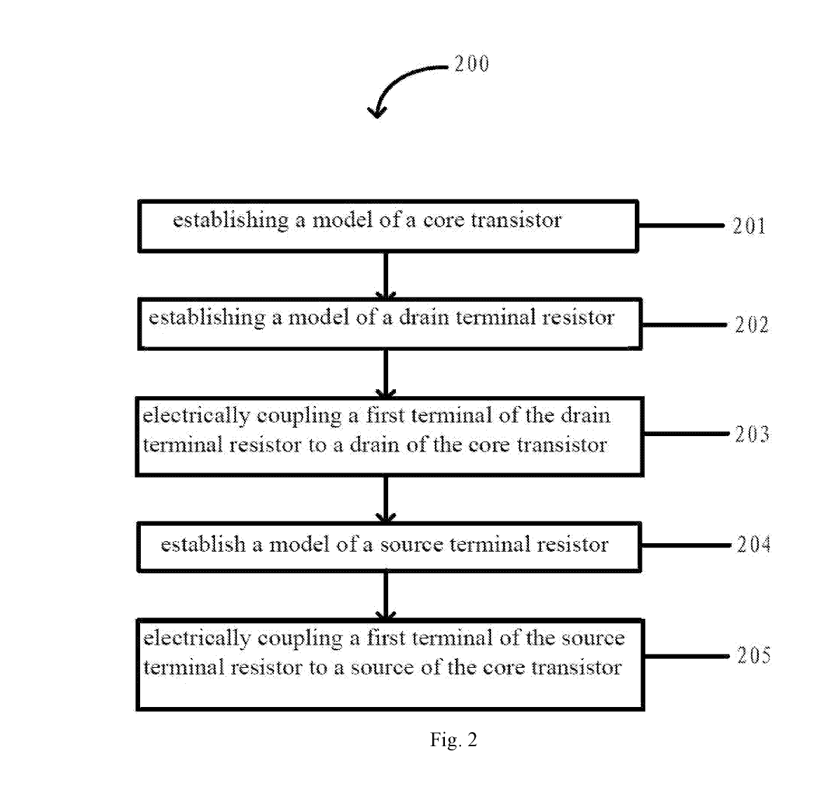

According to another aspect, a modeling method of a simulation model of a high voltage device is provided. FIG. 2 shows a flow chart of the modeling method 200 of the simulation model of the high voltage device. The modeling method 200 will be described with reference to FIG. 1 and FIG. 2 in the following. The modeling method 200 includes in step 201 a model of the core transistor 101 is established. In step 202 a model of the drain terminal resistor 102 is established. In step 203 the first terminal of the drain terminal resistor 102 is electrically coupled to the drain of the core transistor 101. In step 204, a model of the source terminal resistor 103 is established. In step 205, the first terminal of the source terminal resistor 103 is electrically coupled to the source of the core transistor 101. The relationship among a resistance value of the drain terminal resistor 102 and a voltage applied to the drain terminal resistor 102, a temperature and a width of the high voltage device is:

RD=(RD0/W)*(1+CRD*V_{D}^{ERDD}+1/(1+PRWDD*V_{D}^{ERDD}))*TFAC_RD, TFAC_RD=(1+TCRD1*(TEMP−25)+TCRD2*(TEMP−25)*(TEMP−25)).

The relationship among a resistance value of the source terminal resistor 103 and a voltage applied to the source terminal resistor 103, the temperature and the width of the high voltage device is:

RS=(RS0/W)*(1+CRS* V_{S}^{ERSS}+1/(1+PRWSS*V_{S}^{ERSS}))*TFAC_RS, TFAC_RS=(1+TCRS1*(TEMP−25)+TCRS2*(TEMP−25)*(TEMP−25)).

V_{D} is an absolute value of the voltage applied to the drain terminal resistor 102, RD0 is the resistance value of the drain terminal resistor 102 when the voltage is 0, CRD is a first voltage coefficient of the drain terminal resistor 102, ERDD is an exponent term coefficient of the voltage of the drain terminal resistor 102, PRWDD is a second voltage coefficient of the drain terminal resistor 102, TCRD1 is a one degree term temperature coefficient of the drain terminal resistor 102, TCRD2 is a quadratic term temperature coefficient of the drain terminal resistor 102, V_{S} is an absolute value of the voltage applied to the source terminal resistor 103, RS0 is the resistance value of the source terminal resistor 103 when the voltage is 0, CRS is a first voltage coefficient of the source terminal resistor 103, ERSS is an exponent term coefficient of the voltage of the source terminal resistor 103, PRWSS is a second voltage coefficient of the source terminal resistor 103, TCRS1 is a one degree term temperature coefficient of the source terminal resistor 103, TCRS2 is a quadratic term temperature coefficient of the source terminal resistor 103, TEMP is a system temperature, W is a channel width of the high voltage device.

Those skilled in the art should understand that each step of the modeling method 200 can be combined, deleted or replaced according to requirements, and can be performed in any suitable order, which is not limited by the invention. For example, in an embodiment, step 202 and step 203 can be combined in a step to be performed, step 204 and step 205 can be combined in a step to be performed. In another embodiment, step 204 can be performed before step 203. In an yet another embodiment, step 204 and step 205 can be performed before step 202 and step 203.

In an embodiment, the modeling method 200 can further includes establishing a model of at least one drain terminal diode; coupling each of the at least one drain terminal diode in series between the second terminal of the drain terminal resistor and a bulk electrode of the core transistor; establishing a model of at least one source terminal diode; coupling each of the at least one source terminal diode in series between the second terminal of the source terminal resistor and the bulk electrode of the core transistor; and turning off a built-in diode of the core transistor. Those skilled in the art should understand that modeling steps regarding to the at least one drain terminal diode and the at least one source terminal diode can be combined, deleted or replaced according to requirements, and can be performed in any suitable order, which is not limited by the invention.

In the above description regarding to the embodiments of the simulation model of the high voltage device, the core transistor, the drain terminal resistor, the source terminal resistor, the at least one drain terminal diode and the at least one source terminal diode involved in the modeling method of the simulation model of the high voltage device have been described. For simplicity, their detailed descriptions are omitted. Those skilled in the art can understand their specific structures and operational manners with reference to FIG. 1 and FIG. 2 and in combination with the above description.

An exemplary simulation model example created by the modeling method provided in an embodiment according to an embodiment is as follows:

```
        .subckt mn d g s b w = 1E−6 1 = 1E−6
        .param
        +rd0 = 0 rs0 = 0 crd = 0
        +erdd = 1 prwdd = 0 crs = 0
        +erss = 1 prwss = 0 tcrd1 = 0
        +tcrd2 = 0 tcrs1 = 0 tcrs2 = 0
        .param
        +tfac_rd=’ (1+tcrd1*(temper−25)+tcrd2*(temper−25)*(temper−25))’
        .param
        +tfac_rs=’ (1+tcrs1*(temper−25)+tcrs2*(temper−25)*(temper−25))’
        mcore d1 g s1 b mn_core w=w 1=1 as=0 ps=0 ad=0 pd=0
        rd1 d d1
        ‘(rd0/w)*(1+crd*pwr(abs(v(d,d1)),erdd)+1/(1+prwdd*pwr(abs(v(d,d1)),erdd
)))* tfac_rd’
        rs1 s1 s
        ‘(rs0/w)*(1+crs*pwr(abs(v(s1,s)),erss)+1/(1+prwss*pwr(abs(v(s1,s)),erss)))
* tfac_rs’
        d_db_field b d d_db_field area= 1e−12 pj=3e−6
        d_db_gate b d d_db_gate area= 1e−12 pj=1e−6
        d_sb_field b s d_sb_field area= 1e−12 pj=3e−6
        d_sb_gate b s d_sb_gate area= 1e−12 pj=1e−6
        .model d_db_field d
        ***** Parameters ***
        +level = 3
        +....................................
        .model d_db_gate d
        ***** Parameters ***
        +level = 3
        +....................................
        .model d_sb_field d
        ***** Parameters ***
        +level = 3
        +....................................
        .model d_sb_gate d
        ***** Parameters ***
        +level = 3
        +....................................
        .model mn_core nmos
        ***** Parameter ***
        +level = 54 version = 4.5 binunit = 2
        +....................................
        +....................................
        .ends mn
```

In the above simulation model example, each parameter refers to:

w: the channel width of the high voltage device; l: the channel length of the high voltage device; rd0: the resistance value of the drain terminal resistor when the voltage is 0; rs0: the resistance value of the source terminal resistor when the voltage is 0; crd: the first voltage coefficient of the drain terminal resistor; erdd: the exponent term coefficient of the voltage of the drain terminal resistor; prwdd: the second voltage coefficient of the drain terminal resistor; crs: the first voltage coefficient of the source terminal resistor; erss: the exponent term coefficient of the voltage of the source terminal resistor; prwss: the second voltage coefficient of the source terminal resistor; trcd1: the one degree term temperature coefficient of the drain terminal resistor; trcd2: the quadratic term temperature coefficient of the drain terminal resistor; trcs1: the one degree term temperature coefficient of the source terminal resistor; trcs2: the quadratic term temperature coefficient of the source terminal resistor; temper: the system temperature; as: the equivalent area of the source of the high voltage device; ps: the equivalent perimeter of the source of the high voltage device; ad: the equivalent area of the drain of the high voltage device; pd: the equivalent perimeter of the drain of the high voltage device; area: the area of the diode; pj: the perimeter of the diode; wherein, inn is the equivalent circuit name of the high voltage device; mn_core is the model name of the core transistor; d_db_field is the model name of the first drain terminal diode; d_db_gate is the model name of the second drain terminal diode; d sb field is the model name of the first source terminal diode; d_sb_gate is the model name of the second source terminal diode.

In the above simulation model example “mcore d1 g s1 b mn_core w=w l=l as=0 ps=0 ad=0 pd=0” is included, wherein as, ps, ad and pd are set as 0, which serves for turning off of the built-in diode of the core transistor.

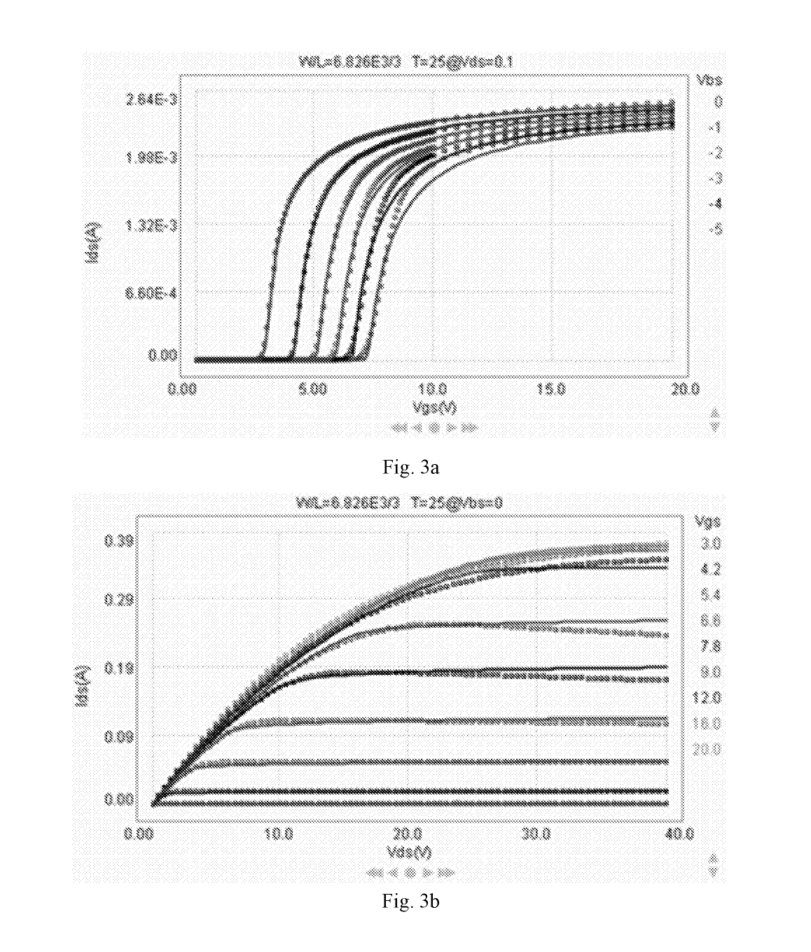

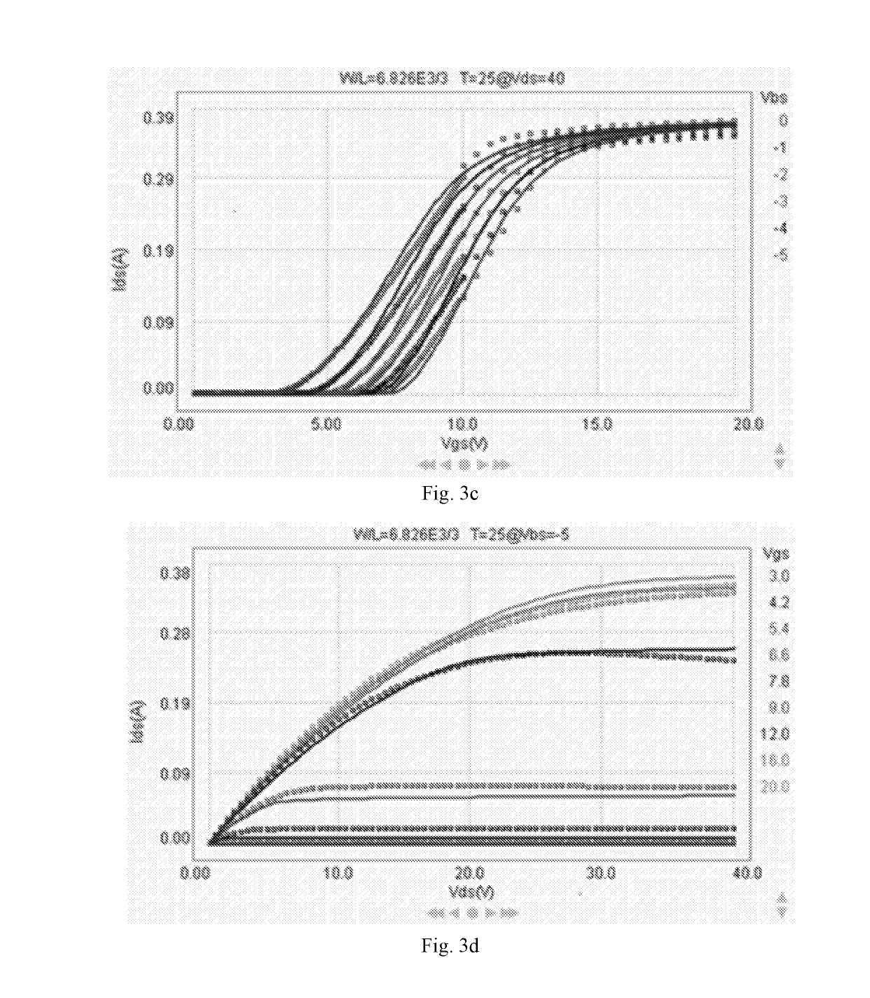

FIGS. 3a-3d are graphs showing curves representing a relationship between a current characteristic and a voltage characteristic for simulating an exemplary high voltage device by using the simulation model of the high voltage device in an embodiment. In FIGS. 3a-3d, the solid line indicates the simulation curve, and the dotted line indicates the actual measurement curve. As shown in FIGS. 3a-3d, the fitting result of simulating the high voltage device by using the simulation model provided by the invention is very good, and can satisfy the higher simulation accuracy required for the high voltage (or ultra high voltage) device.

Although the invention is illustrated and described herein with reference to specific embodiments, the invention is not intended to be limited to the details shown. Rather, various modifications may be made in the details within the scope and range of equivalents of the claims and without departing from the invention.

What is claimed is:

1. A simulation model of a high voltage device, comprising:
a core transistor;
a drain terminal resistor, wherein a first terminal of the drain terminal resistor is electrically coupled to a drain of the core transistor and a second terminal of the drain terminal resistor serves as a drain of the high voltage device; and
a source terminal resistor, wherein a first terminal of the source terminal resistor is electrically coupled to a source of the core transistor and a second terminal of the source terminal resistor serves as a source of the high voltage device;
wherein a relationship among a resistance value of the drain terminal resistor, a voltage applied to the drain terminal resistor, a temperature, and a width of the high voltage device is:
RD=(RD0/W)*(1+CRD*V_{D}^{ERDD}+1/(1+PRWDD*V_{D}^{ERDD}))*TFAC_RD, TFAC_RD=(1+TCRD1*(TEMP−25)+TCRD2*(TEMP−25)*(TEMP−25));
wherein a relationship among a resistance value of the source terminal resistor, a voltage applied to the source terminal resistor, the temperature and the width of the high voltage device is:
RS=(RS0/W)*(1+CRS*V_{S}^{ERSS}+1/(1+PRWSS*V_{S}^{ERSS}))TFAC_RS, TFAC_RS=(1+TCRS1*(TEMP−25)+TCRS2*(TEMP−25)*(TEMP−25));
wherein V_{D} is an absolute value of the voltage applied to the drain terminal resistor, RD0 is the resistance value of the drain terminal resistor when the voltage is 0, CRD is a first voltage coefficient of the drain terminal resistor, ERDD is a exponent term coefficient of the voltage of the drain terminal resistor, PRWDD is a second voltage coefficient of the drain terminal resistor, TCRD1 is a one degree term temperature coefficient of the drain terminal resistor, TCRD2 is a quadratic term temperature coefficient of the drain terminal resistor,
V_{S} is an absolute value of the voltage applied to the source terminal resistor, RS0 is the resistance value of the source terminal resistor when the voltage is 0, CRS is a first voltage coefficient of the source terminal resistor, ERSS is an exponent term coefficient of the voltage of the source terminal resistor, PRWSS is a second voltage coefficient of the source terminal resistor, TCRS1 is a one degree term temperature coefficient of the source terminal resistor, TCRS2 is a quadratic term temperature coefficient of the source terminal resistor,
TEMP is a system temperature, W is a channel width of the high voltage device.

2. The simulation model of claim 1, characterized in that, the simulation model further comprises:
at least one drain terminal diode, wherein each of the at least one drain terminal diode is coupled in series between the second terminal of the drain terminal resistor and a bulk electrode of the core transistor; and
at least one source terminal diode, wherein each of the at least one source terminal diode is coupled in series between the second terminal of the source terminal resistor and the bulk electrode of the core transistor;
wherein a built-in diode of the core transistor is turned off.

3. The simulation model of claim 2, characterized in that, the at least one drain terminal diode comprises a first drain terminal diode and a second drain terminal diode, the first drain terminal diode is a parasitic diode located at an isolation region side of the high voltage device and between the drain of the high voltage device and the bulk electrode of the high voltage device, the second drain terminal diode is a parasitic diode located at a gate side of the high voltage device and between the drain of the high voltage device and the bulk electrode of the high voltage device.

4. The simulation model of claim 2, characterized in that, the at least one source terminal diode comprises a first source terminal diode and a second source terminal diode, the first source terminal diode is a parasitic diode located at an isolation region side of the high voltage device and between the source of the high voltage device and the bulk electrode of the high voltage device, the second source terminal diode is a parasitic diode located at a gate side of the high voltage device and between the source of the high voltage device and the bulk electrode of the high voltage device.

5. The simulation model of claim 1, characterized in that, CRD is a function of a channel length of the high voltage device.

6. The simulation model of claim 1, characterized in that, CRD is a function of the channel width of the high voltage device.

7. The simulation model of claim 1, characterized in that, the core transistor is fitted using a B SIM4 transistor model.

8. A modeling method of a simulation model of a high voltage device, comprising:
establishing a model of a core transistor;
establishing a model of a drain terminal resistor;
electrically coupling a first terminal of the drain terminal resistor to a drain of the core transistor;
establish a model of a source terminal resistor; and
electrically coupling a first terminal of the source terminal resistor to a source of the core transistor;
wherein a relationship among a resistance value of the drain terminal resistor, a voltage applied to the drain terminal resistor, a temperature and a width of the high voltage device is:
RD=(RD0/W)*(1+CRD*V_{D}^{ERDD}+1/(1+PRWDD*V_{D}^{ERDD}))*TFAC_RD, TFAC_RD=(1+TCRD1 *(TEMP−25)+TCRD2*(TEMP−25)*(TEMP−25));
wherein a relationship among a resistance value of the source terminal resistor, a voltage applied to the source terminal resistor, the temperature, and the width of the high voltage device is:
RS=(RS0/W)*(1+CRS*V_{S}^{ERSS}+1/(1+PRWSS*V_{S}^{ERSS}))*TFAC_RS, TFAC_RS=(1+TCRS1*(TEMP−25)+TCRS2*(TEMP−25)*(TEMP−25));
V_{D} is an absolute value of the voltage applied to the drain terminal resistor, RD0 is the resistance value of the drain terminal resistor when the voltage is 0, CRD is a first voltage coefficient of the drain terminal resistor, ERDD is an exponent term coefficient of the voltage of the drain terminal resistor, PRWDD is a second voltage coefficient of the drain terminal resistor, TCRD1 is a one degree term temperature coefficient of the drain terminal resistor, TCRD2 is a quadratic term temperature coefficient of the drain terminal resistor,
V_{S} is an absolute value of the voltage applied to the source terminal resistor, RS0 is the resistance value of the source terminal resistor when the voltage is 0, CRS is a first voltage coefficient of the source terminal resistor, ERSS is an exponent term coefficient of the voltage of the source terminal resistor, PRWSS is a second voltage coefficient of the source terminal resistor, TCRS1 is a one degree term temperature coefficient of the source terminal resistor, TCRS2 is a quadratic term temperature coefficient of the source terminal resistor,
TEMP is a system temperature, W is a channel width of the high voltage device.

9. The modeling method of claim 8, characterized in that, the modeling method further comprises:
establishing a model of at least one drain terminal diode;
coupling each of the at least one drain terminal diode in series between the second terminal of the drain terminal resistor and a bulk electrode of the core transistor;
establishing a model of at least one source terminal diode;
coupling each of the at least one source terminal diode in series between the second terminal of the source terminal resistor and the bulk electrode of the core transistor; and
turning off a built-in diode of the core transistor.
